(19) United States
(12) Patent Application Publication
(10) Pub. No.: US 2010/0288346 A1
(43) Pub. Date: Nov. 18, 2010

(54) Configurations and methods to manufacture solar cell device with larger capture cross section and higher optical utilization efficiency

(76) Inventor: Gobi Ramakrishnan Padmanabhan, Sunnyvale, CA (US)

Correspondence Address: BO-IN LIN, 13445 MANDOLI DRIVE, LOS ALTOS HILLS, CA, 94022, US

(21) Appl. No.: 12/799,594

(22) Filed: Apr. 28, 2010

Related U.S. Application Data
(60) Provisional application No. 61/214,979, filed on Apr. 29, 2009.
(60) Provisional application No. 61/214,941, filed on Apr. 29, 2009.
(60) Provisional application No. 61/214,942, filed on Apr. 29, 2009.

(51) Int. Cl. H01L 31/0288; H01L 31/00; H01L 31/0256; H01L 31/0216

(52) U.S. Cl. 136/255; 136/252; 136/261; 136/256

(57) ABSTRACT

A method of creating a High efficiency solar cell with a Triangular or Sinusoidal parallel Ridge above the surface, below the surface, buried under the surface and also back of the cell to improve capture cross section is described in this invention.

This application claims a priority according to pending U.S. patent application Ser. Nos. 61/214,979, 61/214,941, and 61/914,942 filed on Apr. 29, 2009 by the same Applicant of this Application, the benefits of the filing date of Apr. 29, 2009 are hereby claimed under Title 35 of the United States Code.

### BACKGROUND OF THE INVENTION

1. Field of the Invention

This invention relates generally to the configurations and methods for manufacturing photovoltaic cells for converting optical energy into electric energy. More particularly, this invention relates to configurations and methods to manufacture photovoltaic cells on semiconductor substrate with expanded energy absorbing surface areas and substantially eliminating optical reflection from the surface of the solar cells thus increasing efficiency of current generation from the photovoltaic cells.

2. Description of the Prior Art

Even with wide ranges of research efforts and design creativities devoted to increase the photovoltaic cell efficiency and to expand the photon capture and light utilization areas of solar cells, conventional technologies of manufacturing semiconductor photovoltaic cells are still confronted with a physical limitation that the light capture areas and surface utilization of the solar cells cannot be further increased. Specifically, the solar cells are formed on a semiconductor substrate with the solar cells disposed as with light capture surface disposed on the semiconductor substrate along a horizontal orientation in parallel to the top and bottom surfaces of the substrate. The total surface area of the substrate typically is the maximum area that can be exposed to the sun and utilizable to capture the solar energy into the solar cells.

FIGS. 1A and 1B are a top view and a cross sectional view respectively of a conventional solar cell device supported on a semiconductor substrate. The solar cell device is formed on top a silicon or poly silicon substrate layer 100. The Epitaxial layer 105 is optional and is required only for Silicon cells. The epitaxial layer 105 is not necessary for a poly silicon substrate. An opposite conduction layer 110 is formed on top of the substrate layer; either by diffusion of by implantation followed by anneal process. Thus PN junction is formed in the substrate layer with opposite conduction to the substrate type on top of the substrate. Then an antireflection (AR) layer 120 is formed on the top surface covering the top layer 110. An electrical grid layer 130 and an electrode layer 140 are formed on the top and bottom surface respectively. The photons 170 are pass through the solar cell device, pairs of electron 150 and hole 160 are generated throughout the semiconductor region and electrons are collected in the N-layer and holes in the P layer respectively. The collected electrons 150 and the holes 160 thus accumulated and separated by the PN junction, generate a voltage difference between the top and bottom PN Junction thus converting the optical energy transmitted through the photons into electrical energy.

There are several disclosures related solar cell devices including Patent Publications 20040221886, 20090151637, 20090000656, 20080157106, 20080155908, and 20100006139. These Patent Application Publications disclose various improved configurations in attempt to improve the photovoltaic cell efficiency of the solar energy devices. However, these disclosures are related only to configurations and layout of solar cell modules and assemblies. The techniques and device configurations as disclosed do not provide an effective solution to overcome the limitation intrinsically imposed on the light capture areas due to the physical dimension of the flat surface of the semiconductor substrate.

There was a publication By Stanford University, which deals with crating uneven surface by etching the top surface to produce lots os overlapping Pyramid structures, thereby increasing the capture cross section and also increasing the photon absorption. There is another work by University of Southwales, Australia, essentially trying to achieve the same idea using an inverted Pyramid structure on the top of the substrate.

Therefore, a need still exists in the art of solar cell device design and manufacture to provide new manufacturing method and device configuration in forming the solar cell devices with new and improved configurations such that the above discussed problems and limitations can be resolved.

### SUMMARY OF THE PRESENT INVENTION

A major aspect of this invention is to provide solar panel comprises solar cells manufactured with improved configurations and methods to make the solar cell with larger capture cross sectional area for energy absorbing surface configured to have triangular, rectangular or sinusoidal ridges, which runs almost to the full length of the surface, which can be on the top, buried or at the bottom of the silicon or poly silicon substrate. With this new and improved configuration, the solar cells are made with larger surface cross sectional area, with the same wafer surface. Compared with the conventional photovoltaic solar panels extended over a same horizontal area, the solar panels of this invention that extends across a same horizontal area can produce higher current because the photons now incident onto expanded absorption cross sectional areas.

Another aspect of this invention is to provide solar panel comprises solar cells manufactured with the energy absorbing surface configured to have triangular, rectangular or sinusoidal ridges and with these ridges formed on the top, buried or at the bottom of the silicon or poly silicon substrate. With this new and improved configuration, the solar cells are made with larger surface cross sectional area by using wafers of the same wafer surface thus providing multiple reflection of the photons at the surface of the structure that also produce more electron-hole pairs than the standard conventional solar cells.

Another aspect of this invention is to form ridges buried at the bottom surface of the substrate. The bottom ridge configuration further expands the bottom contact area thus improving the capture rates of holes or electrons depending on the bottom material as P or N type. This configuration also improves the proximity of the portion of the bottom electrode closer to the PN junction, thus increasing current transmission efficiency because of the reduced loss with less substrate resistance.

Briefly, an embodiment of this invention includes a solar cell device. The solar cell device comprises multiple semiconductor layers formed with different conductivity type to form a PN junction in a semiconductor substrate, wherein at least one of the semiconductor layers having a non-flat surface comprises a parallel ridges extend along substantially a same direction. In another embodiment, the non-flat surface comprises the parallel ridges having a sinusoidal ridge shape. In another embodiment, the non-flat surface comprises the parallel ridges having a triangular ridge shape. In another embodiment, the non-flat surface comprises the parallel ridges having a rectangular ridge shape. In another embodiment, the semiconductor substrate is composed of a III/IV semiconductor compound or a IV/V semiconductor compound. In another embodiment, the parallel ridges are disposed on a top surface or formed as a buried junction wherein the parallel ridges are configured to perform as a multiple junction device and to provide a surface capacitance or a junction capacitance for improving a capacitance per unit area, and improving resistance/conductance per unit area characteristics of the semiconductor solar device. In another embodiment, the solar device further comprises an antireflection (AR) layer disposed on a top surface of the semiconductor substrate wherein the AR layer includes a single layer or multiple layers of AR films. In another embodiment, the parallel ridges are formed as a buried junction wherein the parallel ridges are configured to perform as multiple junctions. In another embodiment, the multiple semiconductor layers formed with different conductivity types to form the PN junction in the semiconductor substrate are doped with dopant concentrations for improving absorption of photons projected onto the semiconductor layers.

These advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

FIGS. 1A and 1B are a top view and a cross sectional view respectively of a conventional solar cell device supported on a semiconductor substrate.

FIGS. 2A and 2B are a cross sectional view and top view respectively of an array of photovoltaic cells supported on a semiconductor chip of this invention.

FIGS. 3A to 3I are a series of cross sectional views for illustrating the processing steps to manufacture the array of photovoltaic cells of FIGS. 2A and 2B.

FIGS. 4A to 4c are a cross sectional view, top view and bottom view respectively of an array of photovoltaic cells supported on a semiconductor chip as an alternate embodiment of this invention.

FIGS. 5A to 5D are a series of cross sectional views for illustrating the processing steps to manufacture the array of photovoltaic cells of FIGS. 4A to 4C.

FIGS. 6A and 6B are a cross sectional view and top view respectively of an array of photovoltaic cells supported on a semiconductor chip as another embodiment of this invention.

FIGS. 7A to 7G are a series of cross sectional views for illustrating the processing steps to manufacture the array of photovoltaic cells of FIGS. 6A and 6B.

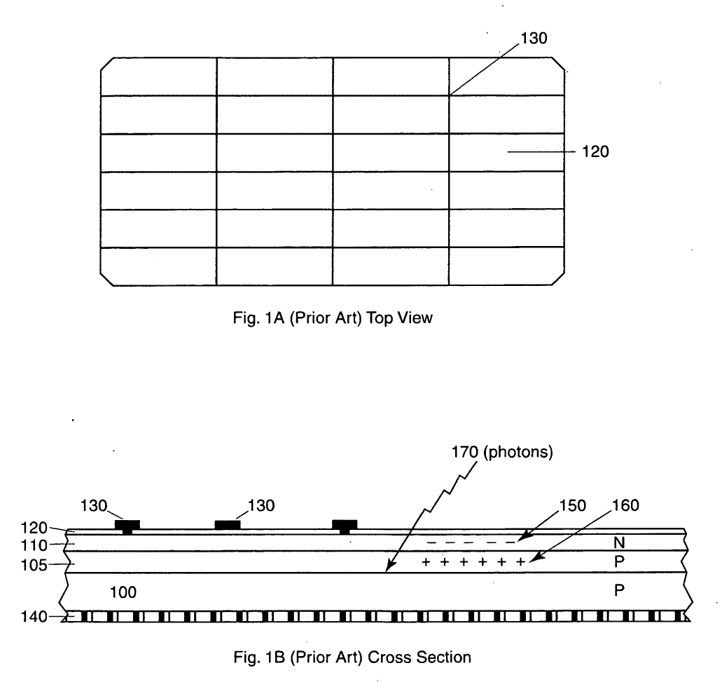

### DETAILED DESCRIPTION OF THE PREFERRED EMBODIMENT

### First Embodiment

### Buried Ridge Case

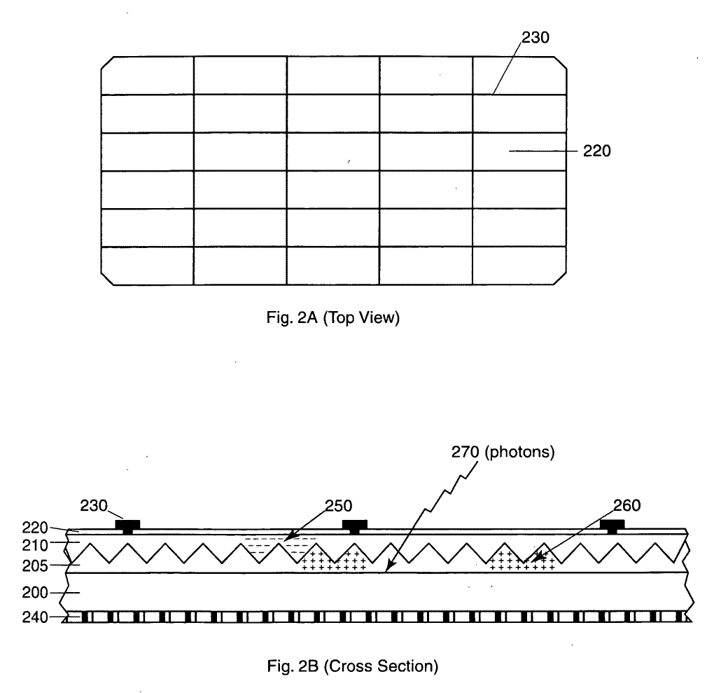

Referring to FIGS. 2A and 2B for a top view and a cross sectional view respectively of a solar cell device of the present invention supported on semiconductor substrate 200. The substrate 200 may be formed as an N or P type substrate, it may also be a single crystal silicon or poly crystal silicon. For a single crystal silicon substrate, an epitaxial layer 205 of the same conductivity type as that of the substrate layer may be formed as an optional layer for the starting substrate. With a silicon substrate layer 200, conduction layer 210 of opposite conductivity type may be formed on the top of silicon layer 200 using either a diffusion or implantation method (in case of epitaxial layer 205) thus forming a PN junction between these two layers. A top surface 210 of an opposite conductivity type from the conductivity type of the substrate 200 is then formed and then covered with an antireflection layer 220. A top electrical contact grid 230 is formed on top of the antireflection layer 220. An electrode is formed on the bottom surface of the substrate 200 to form another ohmic contact for the solar cell device.

As the photons 270 projected onto the top surface, these photons 270 are transmitted through the antireflection layer 220 and pass through the semiconductor regions. Upon reaching the PN junction between the layers of different conductivities types, the irradiation of these photons generates pairs of electron 250 and holes 260 throughout the silicon layers. Then the electrons are separated to N-type layer 210 and holes to P-type layer 205 formed with the PN junction between these two layers. The electron-hole pairs accumulate at these respective layers creating a potential difference and voltage across the PN junction.

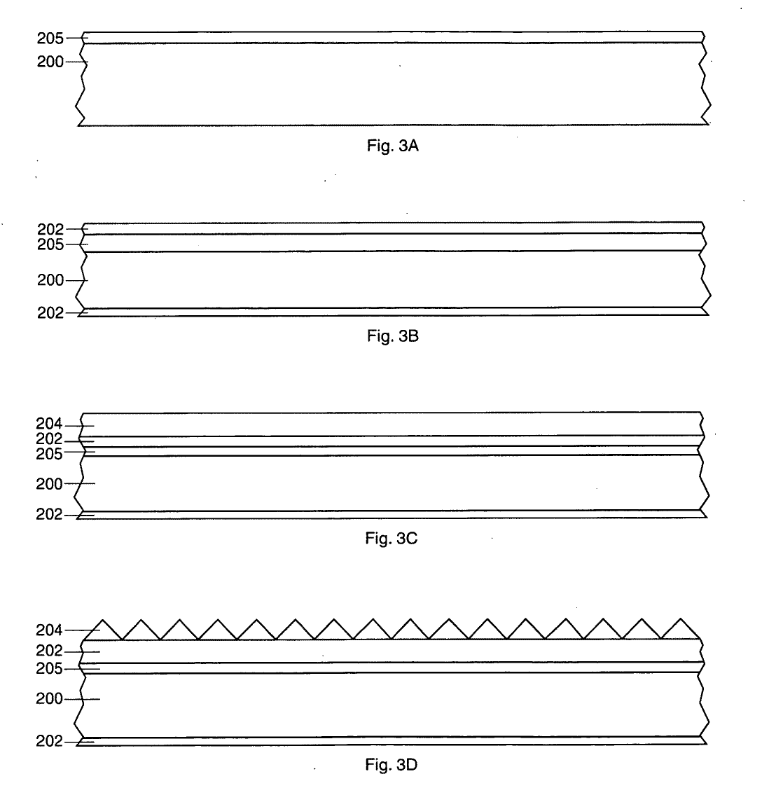

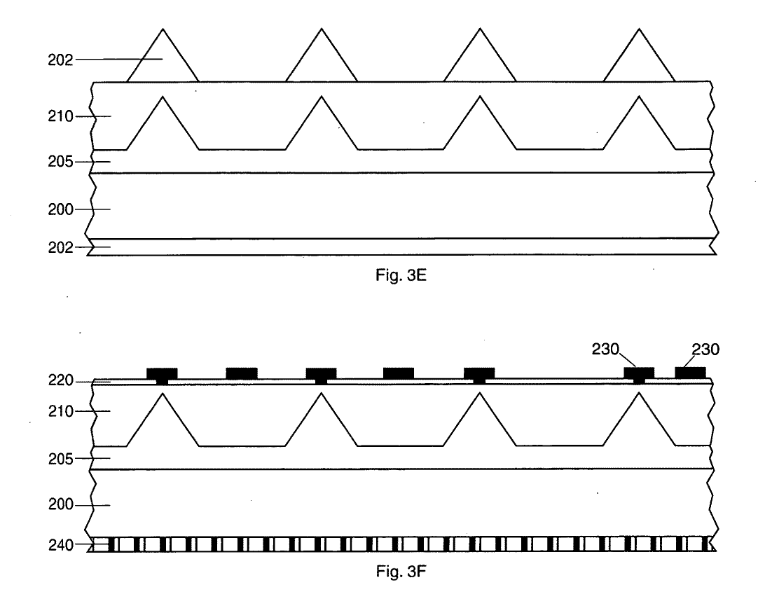

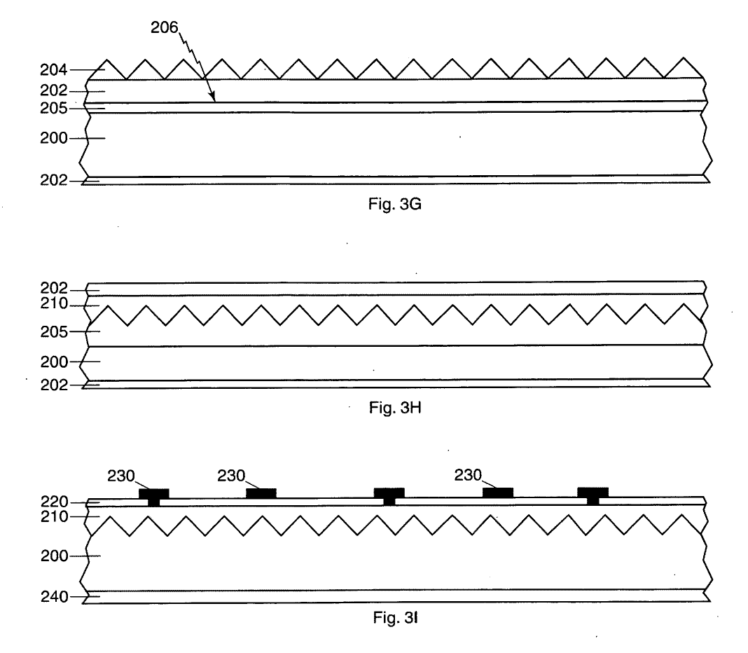

FIGS. 3A to 3I are a series of cross sectional views for illustrating the processing steps for manufacturing the solar cell device of FIGS. 2A and 2B. FIG. 3A shows the manufacturing processes start with a substrate 200 (single crystal silicon N or P type with or without an optional epitaxial layer 205 of the same type as the substrate layer silicon or a poly silicon layer). In FIG. 3B, an oxide layer 202 is added on the on top of the substrate layer 200 (or on epi layer 205 which is optional) either by deposition or by oxidation process. In FIG. 3C, a photo resist layer 204 is formed on top of the oxide layer 202. In FIG. 3D, the photo resist layer 204 is patterned to produce a triangular or sinusoidal ridge shape photo resist layer 204.

In FIG. 3E, an etch process is carried out to etch the oxide layer 202, and the photo resist layer 204 is removed. In FIG. 3F, an opposite type conduction layer to substrate is formed by either diffusion and anneal, For example; if the substrate is P type, N type doping material would be used to produce N type layer 210 on the top so as to produce a PN junction, thus forming a PN junction having a triangular or sinusoidal ridge shape. The oxide layer 202 is removed from the top and bottom surface followed by a process of depositing an antireflection (AR) layer 220 on the top surface and the formation of ohmic contact layer 230 on the top and bottom surface of the solar cell device with the top contact layer forming a contact grid in electrical connection with the Top layer 210. A bottom contact layer 240 is formed for bottom contact

FIGS. 3G to 3I show the alternate processing steps. In FIG. 3G, an ion implant of a dopant is carried out followed the processing step shown in FIG. 3D to form an opposite type region 210 on top of substrate layer 200, thus forming a sinusoidal, triangular or even step junctions into the substrate 200. In FIG. 3I, the photo resist layer 204 and the oxide layer 202 are removed and the junction is formed after an anneal step followed by depositing the antireflection layer 220 and the formation and patterning the ohmic contact grid 230 on the top and bottom electrode 240 at the bottom surface respectively as described above in FIG. 3F.

### Second Embodiment

### Bottom Ridge Case

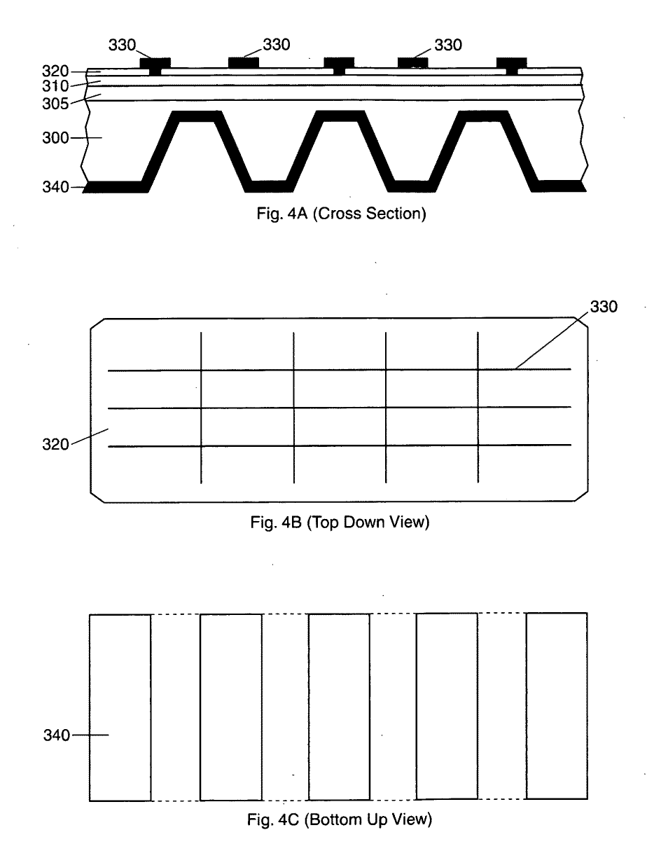

Referring to FIGS. 4A to 4C for a cross sectional view, a top view and a bottom view respectively of a solar cell device of the present invention supported on a semiconductor substrate either N type or P type layer 300. In an embodiment, the substrate can be either a single crystal silicon or poly silicon layer. (With a silicon substrate layer 300, an Epitaxial layer 305 on the top of the same conduction type as the substrate can be optional in some cases). An opposite type layer 310 is formed on top of the substrate layer, thus forming a PN junction between these two layers. The substrate layer 300 is a Bottom Ridge (BR) configuration which runs almost all the way horizontally from one end to another. The top surface of the N-type dopant layer 310 is then covered with an antireflection layer 320. A top ohmic contact grid 330 is formed on top of the antireflection layer 320. An electrode is formed on the bottom surface of the substrate 300 to form another ohmic contact for the solar cell device.

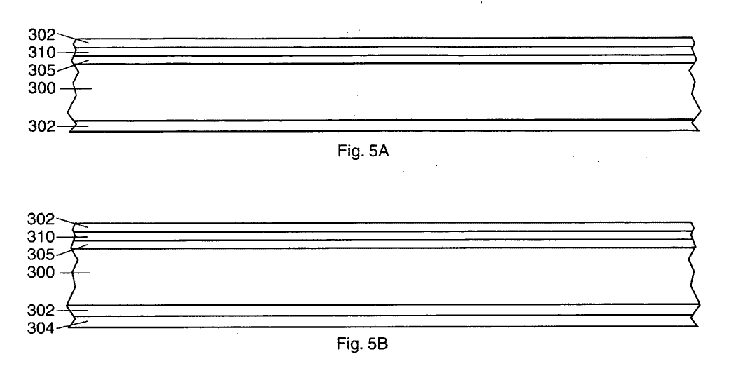

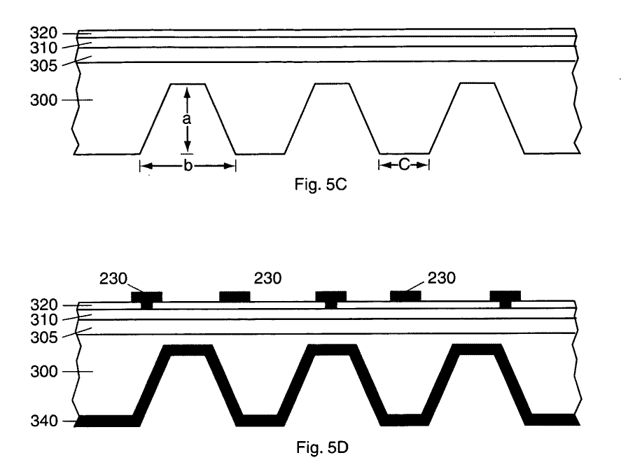

FIGS. 5A to 5D are a series of cross sectional views for illustrating the processing steps for manufacturing the solar cell device of FIGS. 4A to 4C. FIG. 5A shows the manufacturing processes start with a substrate. The substrate may be either an N or P Type or a poly silicon substrate 300. An optical epitaxial layer 305 of the same type as the substrate is formed only for a single crystal silicon substrate 300. A conduction layer 310 of an opposite conductivity type from the substrate layer 310 is formed over the substrate by carrying out a diffusion process or by implanting and followed by an anneal process. An oxide layer 302 is either deposited or grown at the bottom of the substrate layer. In FIG. 5B, a photo resist layer 304 is formed on the bottom surface below the oxide layer 302. In FIG. 5C, the photo resist layer 304 is patterned by masking, exposing, and developing processes. Then an etch process is carried out to etch the back side oxide layer 302 the wafer is ready for performing a partial etch step on the layer 300.

FIG. 5D shows the cross section after the layer 200 is partially etched either wet or dry or combination of the two methods to a depth “a” which is in 10s of microns and is stopped just few microns from the back of the PN Junction, then the photo layer and the back side oxide layer is removed. The width of the “valley of the ridge is designated by a parameter “b” that is also in 10s of microns or even in millimeters or even centimeters. This creates the inverted ridge on the bottom surface of the solar cell device. The pitch between adjacent ridges is designated by a parameter “c” and the length of “c” could be in microns, 10s of microns or in millimeters or even in centimeters. FIG. 5D shows the finished wafer cross section. Layer 320 is the Anti reflection (AR) coating. Layer (330) is the top side ohmic grid contact either on the top of layer 320, to contact layer 310. The bottom ohmic contact is made all across the bottom layer including the valley portions of the ridge in the reverse ridge bottom surface. This produces an increased contact area and also some of the contact area closer to the bottom of the PN junction thus reducing the mean free path for the electrons or holes can be collected by the bottom electrode.

### Third Embodiment

### Above Ridge Case

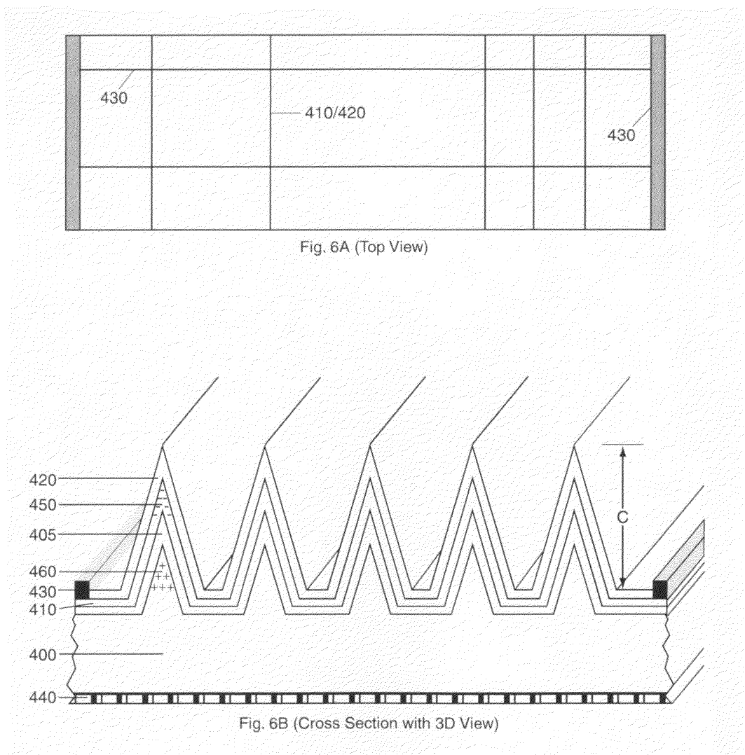

Referring to FIGS. 6A and 6B for a top view and a cross sectional view respectively of a solar cell device of the present invention supported on a silicon substrate 400 which has the above surface ridge which extends horizontally across almost the full length of the cell. The ridges can be triangle or sinusoidal shapes too. In an embodiment, the substrate can either be a single crystal silicon or poly silicon layer, N or P type. With a silicon substrate layer 400, an epitaxial layer 405 can be added which is optional is only for single crystal silicon. An opposite conduction layer 410 is formed on top of the substrate layer thus forming a PN junction between these two layers.

An antireflection (AR) layer 420 covering the top surface is deposited over layer 410. A top contact grid 430 is formed on top of the antireflection layer 420, to form an ohmic contact. An electrode is also formed on the bottom surface of the substrate 400 to form another ohmic contact for the solar cell device. The electron-hole pairs shown as 450 and 460 are generated and accumulated in layers 405 and 410 of alternate conductivities thus create an electrical potential to conduct a current between the electrodes 430 and 440 disposed on the top and bottom surface of the substrate 400.

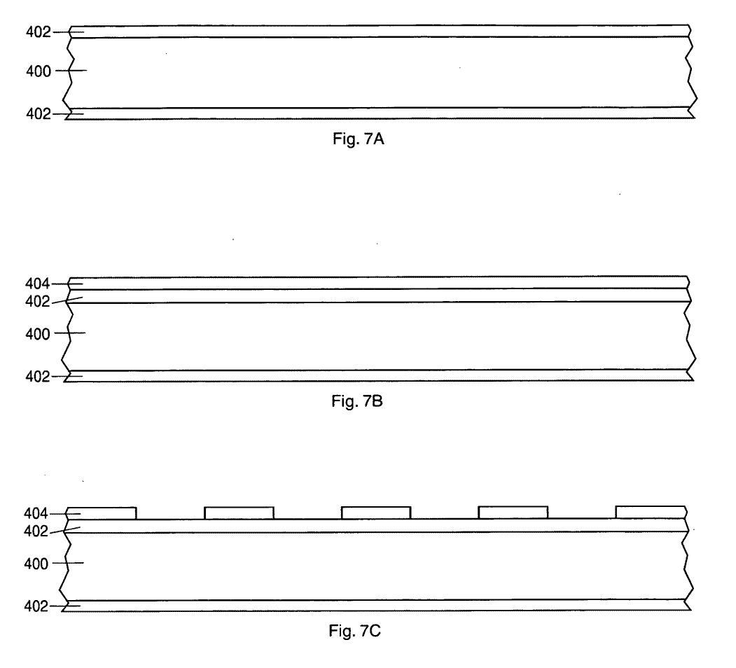

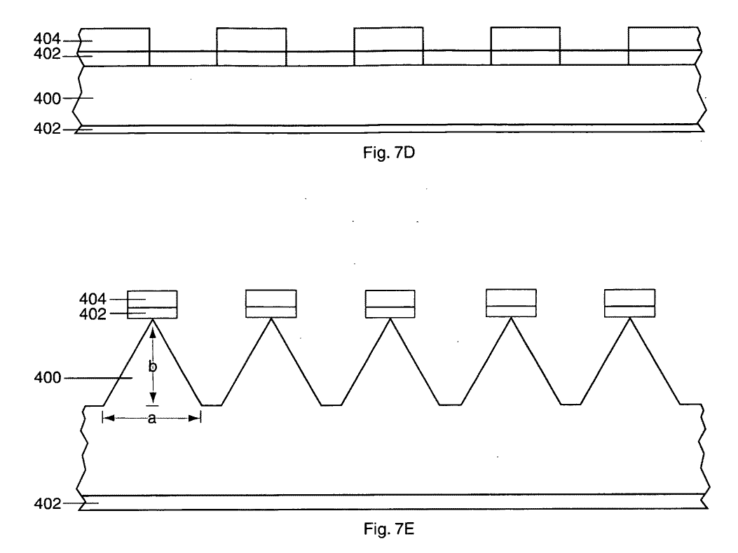

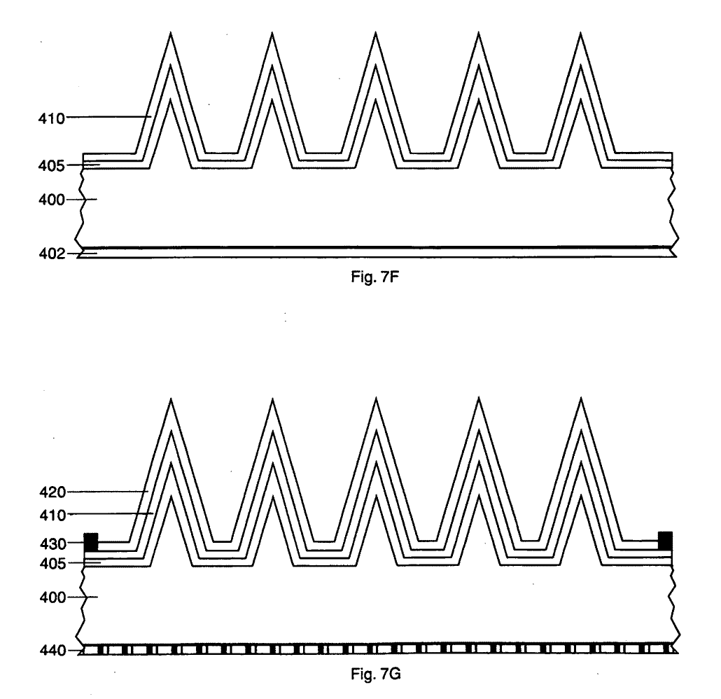

FIGS. 7A to 7G are a series of cross sectional views for illustrating the processing steps for manufacturing the solar cell device of FIGS. 6A and 6B. FIG. 7A shows the manufacturing processes start with a silicon substrate or a polysilicon layer 400 which can be either a P or N type. An oxide layer 402 is grown on top of the substrate layer 400 and at the bottom surface of the substrate layer 400. In FIG. 7B, a photo resist layer 404 is formed on top of the oxide layer 202. In FIG. 7C, the photo resist layer 404 is patterned and in FIG. 7D, the masking, developing and etching processes are carried out to pattern the photo resist layer 404 and the oxide layer 402 ready to carry out an etch process as described below. In FIG. 7E, a silicon etch process is carried out. A wet or dry or wet/dry combination etch process is performed to produce the triangular or sinusoidal ridges on the top surface of the substrate layer 400. Depending on how the mask is designed, a top surface with the triangular or sinusoidal ridges may be formed over all top surface areas as shown in this figure. Alternatively, the triangular or sinusoidal ridges may be etched below the flat or partially above and partially below the top surface. The pitch of the triangular base designated as a parameter “a” and the height of the triangular ridges designated as parameter “b” in FIG. 7E are in 10s of microns or even 100 micron+depending on the objective. In FIG. 7F, the top oxide layer 402 and photo resist layer 402 may still remain on top as shown in FIG. 7E are then removed and the top surface is cleaned. The bottom oxide layer 402 is kept. An optional P type epitaxial layer 405 is grown for a single crystal silicon substrate 400. This is only an optional step. The epitaxial layer 405 is not necessary when the substrate layer 400 is a polysilicon layer. Then the opposite conduction layer 410 is formed on the layer 400 (or 405 as the case may be) is formed by carrying out a diffusion process or by implant followed by an anneal process.

FIG. 7G the back side oxide 402 is removed followed by depositing an antireflection layer 420 on the top surface. Then, an ohmic contact grid 430 either on the top surface 420 for contacting top layer 410 through the AR layer 420. Then an electrode layer 440 is formed on the backside at the bottom surface to create an ohmic contact at the bottom of the substrate layer 400.

With this proposed improved configuration, the solar cells are made with larger surface cross sectional area, with the same wafer surface. With the light absorbing areas formed with triangular or sinusoidal ridge configurations, greater cell efficiency is achieved because of the expanded absorption cross sectional areas. Compared to conventional solar cell devices, higher currents are generated by using the solar cells of this invention formed on the silicon substrate that has a same surface area.

Another advantage of the solar cells of this invention formed with the ridge configuration is the multiple reflections of the photons at the tilted surface of the ridge structure. The photons are prevented from reflected out of the surface and not captured by the light absorbing layers. Therefore, compared to the flat surface devices, more electron hole pairs are generated and greater light utilization is achieved with the improved solar cells of this invention.

Although the present invention has been described in terms of the presently preferred embodiment, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

I claim:

1. A solar cell device comprising multiple semiconductor layers formed with different conductivity type to form a PN junction in a semiconductor substrate wherein:
at least one of the semiconductor layers having a non-flat surface comprises a parallel ridges extend along substantially a same direction.

2. The semiconductor solar device of claim 1 wherein:
said non-flat surface comprises said parallel ridges having a sinusoidal shape.

3. The semiconductor solar device of claim 1 wherein:
said non-flat surface comprises ridges having a triangular ridge shape.

4. The semiconductor solar device of claim 1 wherein:
said non-flat surface comprises ridges having a rectangular ridge shape.

5. The semiconductor solar device of claim 1 wherein:
said non-flat surface comprises the ridges is formed as a buried layer disposed below a top surface of the semiconductor substrate.

6. The semiconductor solar device of claim 1 wherein:
said non-flat surface comprises the ridges is formed partially as a buried layer disposed below a top surface of the semiconductor substrate and partially as protruding ridges protrude above the top surface of the semiconductor substrate.

7. The semiconductor solar device of claim 1 wherein:
said non-flat surface comprises the ridges is formed as a buried layer disposed below a top surface of the semiconductor substrate wherein the top surface is a flat top surface.

8. The semiconductor solar device of claim 1 further comprising:
an antireflection (AR) layer disposed on a top surface of the semiconductor substrate.

9. The semiconductor solar device of claim 1 wherein:
said non-flat layer comprises the ridges is a bottom semiconductor layer with the ridges formed and extending out from a bottom surface of the semiconductor substrate and covered by a bottom electrode layer.

10. The semiconductor solar device of claim 1 wherein:
said non-flat layer comprises the ridges is formed as a top semiconductor layer with the ridges protruding and extending out from a top surface of the semiconductor substrate.

11. The semiconductor solar device of claim 1 wherein:
said semiconductor substrate comprises a single crystal silicon substrate covered by an epitaxial layer of the same conductivity type over the non-flat layer comprises the ridges,

12. The semiconductor solar device of claim 1 wherein:
said semiconductor substrate comprises a poly silicon substrate with the ridges formed

13. The semiconductor solar device of claim 1 wherein:
said semiconductor substrate comprises a single crystal silicon substrate with an Epitaxial layer of the same type and a Ridge shape PN Junction formed within the Epitaxial layer with an AR coating on top of the surface with top electrode contact and Bottom of the substrate with bottom contact

14. The semiconductor solar device of claim 1 wherein:
said semiconductor substrate comprises a poly silicon substrate with Ridge Shaped Junction formed under the top surface

15. The semiconductor solar device of claim 1 wherein:
said semiconductor substrate comprises a single crystal silicon substrate covered on the top by an epitaxial layer of the same type conductivity of the substrate and the PN junction is formed over the epitaxial layer.

16. The semiconductor solar device of claim 15 wherein:
the AR coating is formed on the top side of the surface; and
a contact grid is formed over the AR coating with the parallel ridges formed on a bottom surface of the substrate below the junction; and
a bottom contact layer formed below the contact grid.

17. The semiconductor solar device of claim 1 wherein:
said semiconductor substrate comprises a poly silicon substrate with a PN junction, AR coating on the top of the surface with a Grid contact over the AR coating and the Ridge structure is formed at the bottom of the poly silicon substrate then the bottom contact electrode is applied

18. The semiconductor solar device of claim 1 wherein:
said semiconductor substrate is composed of a III/IV semiconductor compound or a IV/V semiconductor compound.

19. The semiconductor solar device of claim 1 wherein:
said parallel ridges are disposed on a top surface or formed as a buried junction wherein the parallel ridges are configured to perform as a multiple junction device and to provide a surface capacitance or a junction capacitance for improving a capacitance per unit area, and improving resistance/conductance per unit area characteristics of the semiconductor solar device.

20. The semiconductor solar device of claim 1 further comprising:
an antireflection (AR) layer disposed on a top surface of the semiconductor substrate wherein the AR layer includes a single layer or multiple layers of AR films.

21. The semiconductor solar device of claim 1 wherein:
said parallel ridges are formed as a buried junction wherein the parallel ridges are configured to perform as multiple junctions.

22. The semiconductor solar device of claim 1 wherein:
the multiple semiconductor layers formed with different conductivity types to form the PN junction in the semiconductor substrate are doped with dopant concentrations for improving absorption of photons projected onto the semiconductor layers.
